(19) United States
(12) Patent Application Publication
(10) Pub. No.: US 2011/0193202 A1
(43) Pub. Date: Aug. 11, 2011

(54) METHODS TO ACHIEVE 22 NANOMETER AND BEYOND WITH SINGLE EXPOSURE

(75) Inventors: Vincent Yu, Taichung County (TW); Shih-Che Wang, Hsin-Chu City (TW); Chun-Kuang Chen, Hsin-Chu Hsien (TW)

(73) Assignee: TAIWAN SEMICONDUCTOR MANUFACTURING COMPANY, LTD., Hsin-Chu (TW)

(21) Appl. No.: 12/701,104

(22) Filed: Feb. 5, 2010

(51) Int. Cl. H01L 29/06; G03F 7/20

(52) U.S. Cl. 257/632; 430/313; 430/296; 430/325; 430/319; 257/E29.006

(57) ABSTRACT

Apparatus and methods are disclosed herein for fabricating semiconductor device features with a half-pitch node of 22 nm and beyond using single exposure and single etch (1P1E) photolithography techniques. The method includes exposing in a single exposure a photoresist layer to the exposure source through a photolithography mask where the photolithography mask has on it an island pattern of a material having high percentage transmission. The photoresist layer is developed using a negative tone developer to form a hole pattern in the photoresist layer. The 1P1E does not require the second photo exposure of the double patterning method. Furthermore, the method circumvents the island pattern collapsing issues and the need for strong illumination associated with exiting single 1P1E processes.

### TECHNICAL FIELD

The present disclosure relates generally to methods for fabricating semiconductor devices. Specifically, the present disclosure relates to methods for fabricating semiconductor device features with a half-pitch node of 22 nm and beyond using single exposure and single etch photolithography techniques.

### BACKGROUND

Current photolithography tools and processes have the capability to fabricate semiconductor devices with feature sizes below the wavelength of the exposure source. For example, excimer lasers of Argon Fluoride (ArF) having wavelengths (λ) of 193 nm are routinely used to fabricate semiconductor devices with half-pitch nodes of 65 and 45 nm. However, the resolution of a photoresist pattern using current tools begins to blur at a half-pitch of 45 nm. As increasing feature density pushes technology nodes into feature sizes of 22 nm and beyond, resolution enhancement techniques to extend the resolution capability of current photolithography tools are needed. This is especially true given that next generation lithography tools using very short exposure wavelength sources such as extreme ultraviolet (EUV), x-ray, or electron beam are still in development and not yet commercially feasible.

Double patterning is one class of lithographic techniques used to extend the resolution capability of currently available lithography tools into 22 nm nodes and beyond using ArF scanners. Current methods for double patterning include the 2 photo 2 etch (2P2E) and the 2 photo 1 etch (2P1E) methods, both relying on a sequence of two separate exposures of the same photoresist layer using two different masks. In 2P2E, a first exposure of a photoresist layer is followed by an etch. After the photoresist is removed, a second layer of photoresist is deposited and is subject to a second exposure followed by a second etch. The finished photoresist pattern is a composite of the photoresist patterns from the two exposures. However, one drawback with the double patterning technique is that the time delay between the two exposure steps introduces variations into the photoresist patterns. Double patterning also incurs added cost in extra materials and extra processing steps. Furthermore, 2P2E suffers from etching issues associated with the two etching steps.

2P1E attempts to eliminate the first etching step of 2P2E by resist freezing the first developed photoresist layer to modify the surface property of the first photoresist pattern. Surface treatment of the first photoresist pattern protects it from the second exposure step when the second photoresist layer is patterned. While 2P1E may be simpler and more cost effective than 2P2E, the resist freezing process introduces variability in the surface condition of the first exposure pattern, making it difficult to completely protect the first exposure pattern against the second photo exposure. In addition, when the first exposure pattern is an island pattern, 2P1E suffers from serious collapse issue. Furthermore, a reversed process is required when the first exposure pattern is a trench or hole pattern rather than an island pattern.

To circumvent the issues associated with the double patterning methods, single photo, single etch (1P1E) techniques have been proposed. However, these 1P1E methods must use strong illumination to print design features with a tight pitch. As such, the orientation of the exposed patterns is restricted. In addition, current 1P1E methods also suffer from serious collapse issues when the exposure pattern is an island pattern. Accordingly, there exists a need to find photolithographic methods for fabricating technology nodes of 22 nm and beyond that are simple, cost effective, and can avoid the issues arising from the second exposure, resist freezing, etching, and collapsing island patterns associated with existing methods.

### BRIEF SUMMARY

Apparatus and methods are disclosed herein for fabricating semiconductor device features with a half-pitch node of 22 nm and beyond using single exposure and single etch photolithography techniques.

In accordance with one or more embodiments of the present disclosure, a method of fabricating a device using an exposure source is disclosed. The method includes depositing a photoresist layer on a semiconductor substrate. This is followed by exposing in a single exposure the photoresist layer to the exposure source through a photolithography mask where the photolithography mask has on it an island pattern of a partially transmitting material of high percentage transmission. The method also includes developing the photoresist layer using a negative tone developer to form a hole pattern in the photoresist layer. The method further includes etching the semiconductor substrate through the hole pattern in the photoresist layer to form a hole pattern in the semiconductor substrate, and removing the photoresist layer.

In accordance with one or more embodiments of the present disclosure, a method of forming a patterned feature on a substrate is disclosed. The method includes providing an attenuated phase-shift mask (PSM) containing on it an island pattern of a partially transmitting material of high percentage transmission. The method also includes exposing the substrate in a single photo exposure to an exposure source through the island pattern on the PSM. The method further includes developing the exposed substrate using a negative tone developer to form a hole pattern in the substrate.

In accordance with one or more embodiments of the present disclosure, a semiconductor device is disclosed. The semiconductor device includes an oxide layer containing a hole pattern. The hole pattern in the oxide layer is formed from exposing in a single photo exposure a photoresist layer deposited on the oxide layer to an exposure source through a photolithography mask. The photolithography mask contains on it an island pattern of a partially transmitting material that has a percentage transmission of greater than 6%. The exposed photoresist layer is then developed using a negative tone developer. Finally, the oxide layer is etched and the photoresist layer is removed.

These and other embodiments of the present disclosure will be more fully understood by reference to the following detailed description when considered in conjunction with the following drawings.

### BRIEF DESCRIPTION OF THE DRAWINGS

FIGS. 1A through 1G show a cross-sectional view of a semiconductor substrate when using a double photo exposure, single etch (2P1E) photolithographic process to fabricate a hole pattern;

FIG. 2 shows a method for fabricating sub-wavelength device features using a single photo exposure, single etch (1P1E) photolithography process according to one or more embodiments of the present disclosure.

FIGS. 3A through 3B show an island pattern of MbSi on a light field mask with greater than 6% transmission used to pattern a hole pattern on a semiconductor substrate according to one or more embodiments of the present disclosure;

FIGS. 4A through 4C show a cross-sectional view of a sub-λ hole pattern fabricated on a semiconductor substrate using the 1P1E process of FIG. 2 according to one or more embodiments of the present disclosure;

Embodiments of the present disclosure and their advantages are best understood by referring to the detailed description that follows. It should be appreciated that like reference numerals are used to identify like elements illustrated in one or more of the figures.

### DETAILED DESCRIPTION

The present disclosure relates to methods for fabricating semiconductor device features with a half-pitch node of 22 nm and beyond using single exposure and single etch photolithography techniques. It is understood that the present disclosure provides many different foams and embodiments, and that specific embodiments are provided only as examples. Further, the scope of the present disclosure will only be defined by the appended claims. In the drawings, the sizes and relative sizes of layers and regions may be exaggerated for clarity. It will be understood that when an element or layer is referred to as being “on,” “connected to,” or “coupled to” another element or layer, it may be directly on, connected to, or coupled to the other element or layer, or intervening elements or layers may be present.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as being “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein may likewise be interpreted accordingly.

Hereinafter, embodiments of the present invention will be explained in detail with reference to the accompanying drawings.

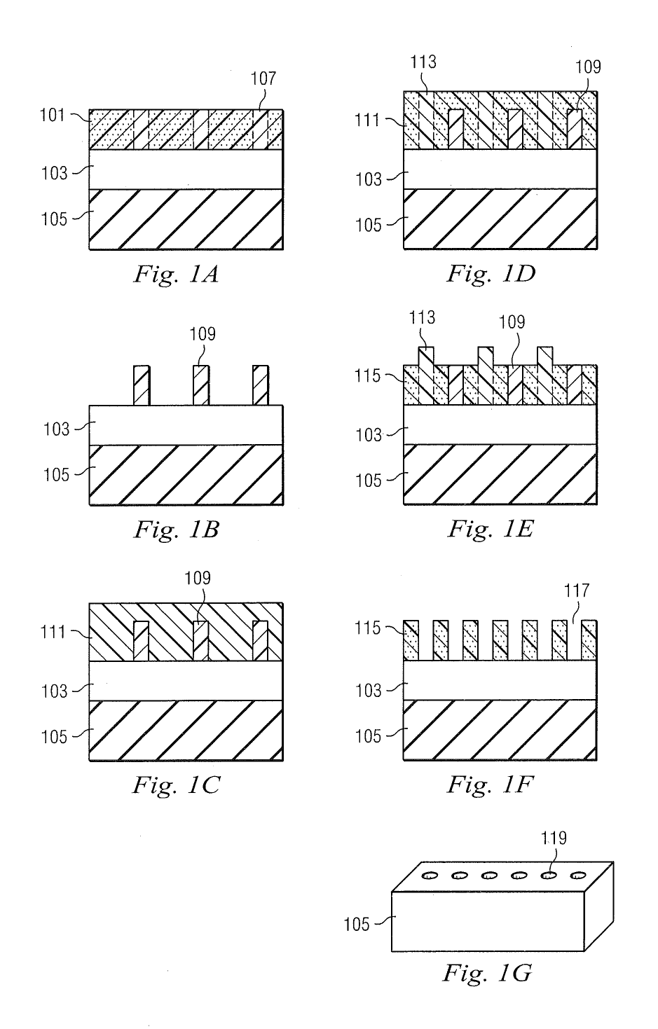

FIGS. 1A through 1G show a cross-sectional view of a semiconductor substrate when using a double photo exposure, single etch (2P1E) photolithographic process to fabricate a hole pattern. 2P1E belongs to the double patterning class of processes commonly used to pattern device with features smaller than the wavelength of the exposure source. It is called double patterning because the process involves a sequence of two separate exposures of the same photoresist layer using two different masks.

The semiconductor substrate consists of a first photoresist layer 101 deposited on a lower layer 103 and an oxide layer 105. In FIG. 1A, in a first exposure step, a first mask is used to expose the first photoresist layer 101 to an exposure source. A pattern of exposed areas and unexposed areas 107 is imaged on the first photoresist layer 101. In FIG. 1B, the exposed areas of the first photoresist layer 101 are developed and removed to form the first island pattern 109. To avoid damaging the first island pattern 109 by a second exposure step, a process of resist freezing is used. In FIG. 1C, the resist freezing process deposits a second photoresist layer 111 over the first island pattern 109 developed from the first photoresist layer 101. The second photoresist layer 111 modifies the surface property of the first island pattern 109 to protect it from the second exposure step.

In FIG. 1D, in the second exposure step, a second mask is used to expose the second photoresist layer 111 to the exposure source. A pattern of exposed areas and unexposed areas is imaged on the second photoresist layer 111. The unexposed areas form a second island pattern 113. In FIG. 1E, a photoresist etching back process is performed to remove an upper layer of the exposed areas of the second photoresist layer 111. The etching back process exposes the first island pattern 109 and also a lower exposed layer 115 of the second photoresist layer 111 without affecting the second island pattern 113. In FIG. 1F, a photoresist stripping process is used to develop the first island pattern 109 and the second island pattern 113 to fowl the hole pattern 117 in the lower exposed layer 115 of the second photoresist layer 111. The hole pattern 117 corresponds to the combined pattern of the first mask and the second mask. Using the hole pattern 117, the lower layer 103 and the oxide layer 105 are etched. Finally in FIG. 1G, the lower exposed layer 115 of the second photoresist layer 111 and the lower layer 103 are removed to form the hole pattern 119 in the oxide layer 105.

It is noted that with the 2P1E process, the time delay between the first and second exposure pattern introduces variations to the patterned features. For example, in FIG. 1, the delay between forming the first island pattern 109 and forming the second island pattern 113 may introduce variations in the final hole pattern 119. In addition, the resist freezing process introduces variability in the surface treatment of the first exposure pattern, making it difficult to completely protect the first exposure pattern from the second photo exposure. In the case of an island pattern as the first exposure pattern, the variability in the resist freezing process may cause some of the islands to collapse. Furthermore, resist freezing process incurs extra cost in material and processing step. Therefore, it is advantageous to have a process that requires only a single exposure step.

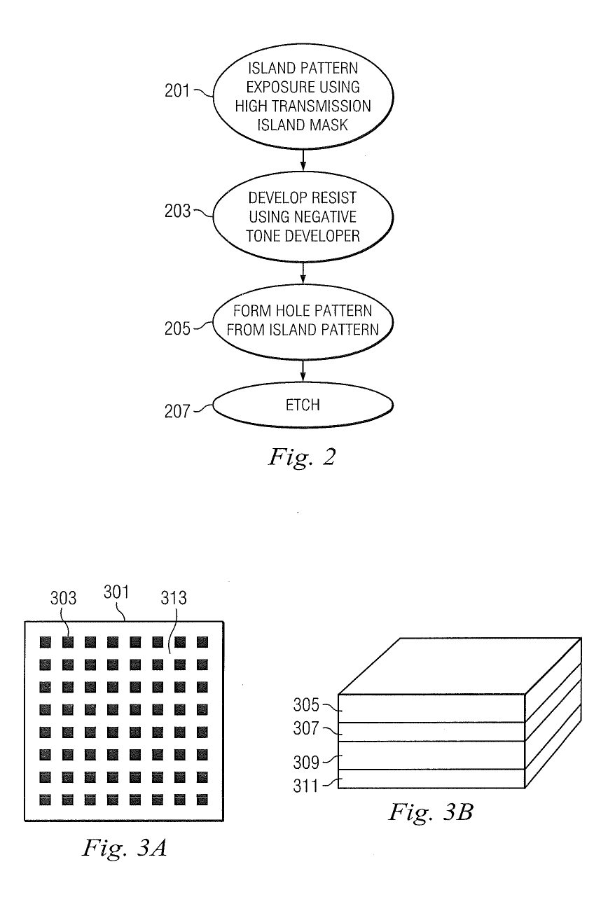

FIG. 2 shows a method for fabricating sub-wavelength device features using a single photo exposure, single etch (1P1E) photolithography process according to one or more embodiments of the present disclosure. The exposure source may have a wavelength from the deep ultraviolet band such as an excimer laser of argon fluoride (ArG) having a wavelength (λ) of 193 nm. Alternatively, non-optical lithography exposure sources having wavelengths in the extreme ultraviolet or X-ray range, or an electron beam exposure source may be used. The exposure source is used to fabricate patterns with feature sizes below the wavelength of the exposure, such as those found on semiconductor devices with half-pitch nodes of 22 nm and beyond.

Step 201 applies the exposure source to a high transmission mask with an island pattern to effect sub-wavelength (sub-λ) photolithographic printing on a wafer. One way to achieve sub-λ patterning is to take advantage of the optical diffraction between adjacent patterns when the exposure source is applied through a phase-shift mask (PSM). PSM relies on the property that light passing through a transparent media undergoes a phase shift as a function of the optical thickness of the media. The optical thickness of a media itself is a function of the refractive index and the thickness of the media. By selecting a material with the desired refractive index and by adjusting the thickness of the material, light transmitted through the material may be made to undergo a phase shift of 180°. Thus, by patterning the phase shifting material of the desired thickness on the mask, light from shifted and unshifted areas of the mask may destructively interfere to achieve sub-λ patterning. For example, at a phase edge between the 0° and the 180° phase shifted areas of the mask, a sub-λ line width may be patterned. Additional benefits of having phase reversals at the edge of the patterned feature are an enhanced image contrast and a higher normalized image log slope (NILS), resulting in improved process latitudes.

Common types of PSMs include alternating PSMs and attenuated PSMs. In alternating PSMs, areas of 0° phase shift and 180° phase shift may be formed on either sides of a line to be printed on a wafer coated with a positive photoresist layer. To create the 180° phase shift area, a subtractive etch of the quartz substrate of the mask may be performed. By contrast, in attenuated PSMs, an energy-absorbing, partially-transmitting film layer may be patterned on a quartz substrate. The energy-absorbing layer may be made of molybdenum silicon (MbSi) to introduce a 180° phase shift of the light transmitted through the layer compared to the light transmitted through the quartz substrate of the mask. Attenuated PSMs may further be classified based on the pattern exposed through the energy absorbing layer. For example, on a dark field attenuated PSM, the background is exposed through the energy absorbing layer, while on a light field attenuated PSM, the device features are exposed through the energy absorbing layer.

The energy-absorbing layer on the attenuated PSM causes an attenuation of the exposure λ through the layer. The extent of the attenuation is determined by the thickness and the absorption coefficient of the material used for the energy-absorbing layer. The amount of attenuation is characterized as a percentage transmission. A typical attenuated PSM has a 6% transmission. The high transmission mask of step 201 uses attenuated PSMs with greater than 6% transmission. This is because using attenuated PSMs with the higher percentage transmission has been shown to improve the mask error enhancement factor (MEEF) and the NILS. Further improvement in MEEF may be achieved by using a light field attenuated PSM rather than a dark field attenuated PSM.

The high transmission mask of step 201 is patterned with an island pattern of the energy-absorbing layer. FIGS. 3A through 3B show an island pattern 303 of MbSi on a light field mask 301 with greater than 6% transmission used to pattern a hole pattern on a semiconductor substrate according to one or more embodiments of the present disclosure. An island pattern on a light field mask is selected because it has been shown that an island pattern on a light field mask exposes device features with enhanced contrast and improved NILS compared to features exposed through a hole pattern on a dark field mask. In FIG. 3A, the island pattern 303 is a pattern of MbSi layered on a substrate of transparent quartz. Areas of the light field mask 301 free of the island pattern 303 are shown as the clear area 313. In FIG. 3B, the semiconductor substrate to be patterned includes an upper photoresist layer 305, a middle layer 307, a lower layer 309, and an oxide layer 311. The island pattern 303 is used to print a pattern of holes or trenches on the photoresist layer 305. Areas of the photoresist layer 305 exposed to the exposure λ through the clear areas 313 of the light field mask 301 correspond to the background area of the hole pattern. Conversely, areas of the photoresist layer 305 unexposed to the exposure λ due to the 180° phase shift introduced by the island pattern 303 of the light field mask 301 correspond to the holes of the hole pattern.

Referring back to FIG. 2, in step 203, the hole pattern of the photoresist layer 305 is developed using a negative tone developer. The negative tone developer dissolves the unexposed areas of the photoresist layer 305 corresponding to the holes of the hole pattern. Using the negative tone developer to develop a photoresist exposed with the island pattern of the light field mask has been shown to achieve better exposure latitude and MEEF compared to using a positive tone developer to develop a photoresist exposed with a hole pattern of a dark field mask. The result is that the hole pattern on the photoresist layer 305 is printed from the island pattern of the mask, as shown in step 205. In step 207, the middle layer 307, the lower layer 309, and the oxide layer 311 of the semiconductor substrate are etched through the hole pattern on the photoresist layer 305 to form the hole pattern in the oxide layer 311.

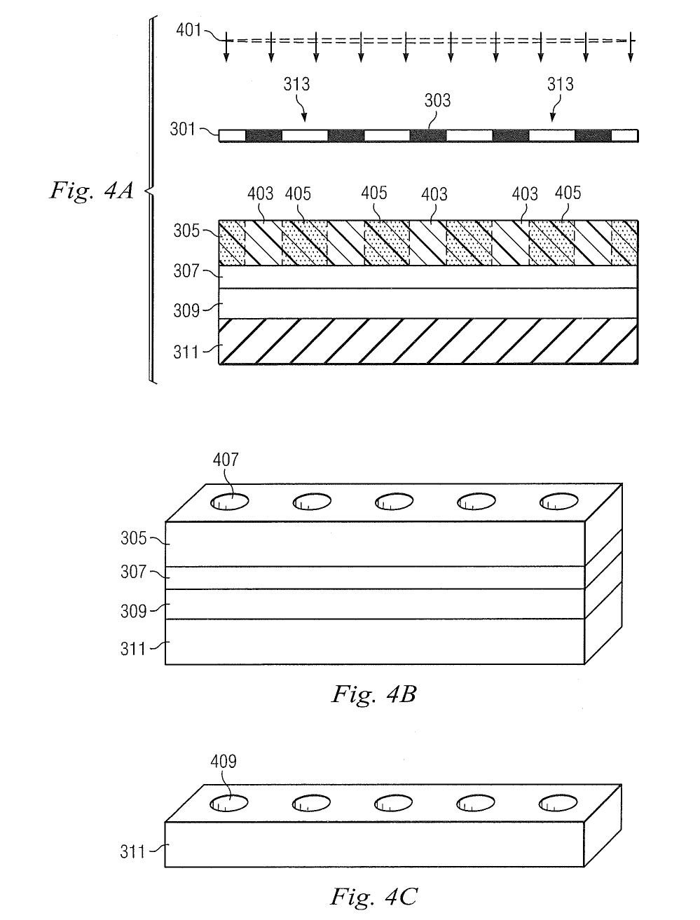

FIGS. 4A through 4C show a cross-sectional view of a sub-λ hole pattern fabricated on a semiconductor substrate using the 1P1E process of FIG. 2 according to one or more embodiments of the present disclosure. In FIG. 4A, exposure λ 401 from the exposure source is transmitted through the light field mask 301 that includes clear areas 313 and an island pattern 303 having greater than 6% transmission. Exposure λ transmitted through the island pattern 303 experiences a phase shift of 180° relative to the exposure λ transmitted through the clear areas 313. The semiconductor substrate to be patterned is as described previously for FIG. 3B. Corresponding to the island pattern 303, unexposed areas 403 of the photoresist 305 are patterned where there is destructive cancellation of the phase shifted and unshifted exposure λ. Conversely, corresponding to the clear areas 313, exposed areas 405 of the photoresist 305 are patterned. In FIG. 4B, the unexposed areas 403 are developed using a negative tone developer to form the hole pattern 407 on the photoresist layer 305. The middle layer 307, lower layer 309, and oxide layer 311 of the semiconductor substrate are then etched through the hole pattern 407. Finally in FIG. 4C, the photoresist layer 305, middle layer 307, and lower layer 309 are removed to form the hole pattern 409 in the oxide layer 311.

The 1P1E method of the present disclosure is cost-effective and simple because it does not require the second photo exposure of the double patterning method. Thus, there is no issue with variations in the photoresist patterns due to the delay between the two exposure steps. It also avoids the etching issues of the 2P2E process. In addition, the 1P1E method overcomes the drawbacks of the 2P1E process such as the variability in the ability of the resist freezing step to protect the first pattern from the second photo exposure, the risk of island pattern collapsing, the need for a reversed process when patterning trench or hole patterns, and the cost of the freezing materials. Furthermore, the method circumvents the island pattern collapsing issues and the need for strong illumination associated with exiting 1P1E processes.

Although embodiments of the present disclosure have been described, these embodiments illustrate but do not limit the disclosure. It should also be understood that embodiments of the present disclosure should not be limited to these embodiments but that numerous modifications and variations may be made by one of ordinary skill in the art in accordance with the principles of the present disclosure and be included within the spirit and scope of the present disclosure as hereinafter claimed.

We claim:

1. A method of fabricating a device using an exposure source comprising:
depositing a photoresist layer on a semiconductor substrate;
exposing in a single photo exposure the photoresist layer to the exposure source through a photolithography mask wherein the photolithography mask has thereon an island pattern of a partially transmitting material of high percentage transmission;
developing the photoresist layer using a negative tone developer to form a hole pattern in the photoresist layer;
etching the semiconductor substrate through the hole pattern in the photoresist layer to form a hole pattern in the semiconductor substrate; and
removing the photoresist layer.

2. The method of claim 1, wherein the partially transmitting material has a percentage transmission of greater than 6%.

3. The method of claim 2, wherein the partially transmitting material is molybdenum silicon (MbSi).

4. The method of claim 1, wherein the photolithography mask is an attenuated phase-shift mask (PSM).

5. The method of claim 1, wherein the photolithography mask is a light field mask wherein holes in the hole pattern of the photoresist layer are unexposed to the exposure source due to the island pattern of the partially transmitting material of the light field mask.

6. The method of claim 5, wherein the negative tone developer dissolves the unexposed holes of the photoresist layer to form the hole pattern in the photoresist layer.

7. The method of claim 1, wherein the photolithography mask is a light field mask wherein a background area in the hole pattern of the photoresist layer is exposed to the exposure source through areas other than the island pattern of the partially transmitting material of the light field mask.

8. The method of claim 1, wherein the exposure source has a wavelength in the deep ultraviolet band.

9. The method of claim 1, wherein the exposure source has a wavelength in the extreme ultraviolet band.

10. The method of claim 1, wherein the exposure source has a wavelength in the x-ray band.

11. The method of claim 1, wherein the exposure source is an electron beam.

12. The method of claim 1, wherein the hole pattern in the semiconductor substrate has a half-pitch of 22 nm and beyond.

13. A method of forming a patterned feature on a substrate comprising:
providing an attenuated phase-shift mask (PSM) containing thereon an island pattern of a partially transmitting material of high percentage transmission; and
forming a hole pattern in the substrate by using the island pattern on the PSM by exposing in a single photo exposure the substrate to an exposure source and developing the exposed substrate using a negative tone developer.

14. The method of claim 13, wherein the partially transmitting material has a percentage transmission of greater than 6%.

15. The method of claim 13, wherein the substrate is a semiconductor wafer with a layer of photoresist.

16. The method of claim 15, wherein the PSM is a light field mask wherein holes in the hole pattern of the photoresist layer are unexposed to the exposure source due to the island pattern of the partially transmitting material of the light field mask.

17. The method of claim of claim 16, wherein the negative tone developer dissolves the unexposed holes of the photoresist layer to form the hole pattern of the photoresist layer.

18. The method of claim 13, further comprising a background area of the hole pattern wherein the background area is exposed to the exposure source through areas other than the island pattern of the partially transmitting material.

19. The method of claim 13, wherein the hole pattern has a half-pitch of 22 nm and beyond.

20. A semiconductor device comprising:
an oxide layer;
a photoresist layer over the oxide layer;
a hole in the oxide layer formed by exposing the photoresist layer in a single photo exposure to an exposure source through a photolithography mask, developing the exposed photoresist layer using a negative tone developer, and etching the oxide layer, wherein the photolithography mask includes an island pattern of a partially transmitting material having a percentage transmission of greater than 6%.
